(19) United States
(12) Patent Application Publication
(10) Pub. No.: US 2023/0420423 A1
(43) Pub. Date: Dec. 28, 2023

(54) BACKLIGHT UNIT, DISPLAY DEVICE COMPRISING SAME, AND METHOD FOR MANUFACTURING DISPLAY DEVICE

(71) Applicant: LG ELECTRONICS INC., Seoul (KR)

(72) Inventors: Soohyun KIM, Seoul (KR); Junoh SHIN, Seoul (KR); Youngdo KIM, Seoul (KR); Wonseok CHOI, Seoul (KR); Dohan KIM, Seoul (KR)

(73) Assignee: LG ELECTRONICS INC., Seoul (KR)

(21) Appl. No.: 18/247,789

(22) PCT Filed: Oct. 6, 2020
(86) PCT No.: PCT/KR2020/013598

§ 371 Date: Apr. 4, 2023

(51) Int. Cl. H01L 25/075; H01L 33/62

(52) U.S. Cl. CPC H01L 25/0753; H01L 2933/0066; H01L 33/62

(57) ABSTRACT

A display device according to embodiments of the present invention comprises: a substrate; a plurality of first metal wiring layers formed on the substrate; a first insulating layer stacked on the substrate to cover the first metal wiring; a second metal wiring layer stacked on at least a portion of the first insulating layer so as to be spaced apart therefrom; and a second insulating layer stacked on the second metal wiring. The second metal wiring layer comprises: at least one first metal layer having a first conductivity; and at least one second metal layer having a higher conductivity than the first metal layer, wherein the first metal layer may block diffusion of the second metal layer.

### TECHNICAL FIELD

The present disclosure is applicable to a display device-related technical field, and relates to, for example, a display device using a backlight unit and a light emitting device (light emitting diode, LED) and a method for manufacturing the display device.

### BACKGROUND

Recently, in a field of a display technology, display devices having excellent characteristics such as thinness, flexibility, and the like have been developed. On the other hand, currently commercialized major displays are represented by an LCD (liquid crystal display) and an OLED (organic light emitting diode).

An LED (light emitting diode), which is a well-known semiconductor light-emitting device that converts electric current into light, has been used as a light source for a display image of an electronic device including an information and communication device along with a GaP:N-based green LED, starting with commercialization of a red LED using a GaAsP compound semiconductor in 1962. Accordingly, a method for solving the above-described problems by implementing a display using the semiconductor light-emitting device may be proposed.

In this regard, a process of bonding an LED chip, a micro IC, or the like onto a substrate on which a metal wiring is formed using solder is required to manufacture a backlight unit of the LCD. In this regard, a surface mount technology (SMT) for bonding the LED onto the metal wiring is required.

In general, there may be a case using copper (Cu) and a case not using copper (Cu) for the SMT process. In this regard, in a case of using a metal wiring that does not contain Cu, there is a problem in that a solder material is not evenly spread on a metal surface. In addition, there is a problem in that a strength of bonding between the substrate including the metal wiring and the LED chip is weakened due to a thickness of the metal wiring.

Accordingly, embodiments suggest a method for improving the strength of the bonding between the substrate including the metal wiring and the LED chip.

### SUMMARY

### Technical Problem

One object of the present disclosure is to provide a display device and a method for manufacturing the same that reduce a problem of deterioration in a strength of bonding between a semiconductor light emitting device and a metal wiring formed on a substrate.

### Technical Solutions

According to an aspect, a backlight unit includes a substrate including a first metal wiring layer; a first insulating layer disposed on the substrate so as to cover the first metal wiring layer; a second metal wiring layer disposed on the first insulating layer, wherein a plurality of pairs of metal layers including a first metal layer having a first conductivity and a second metal layer having a higher conductivity than the first metal layer are stacked in the second metal wiring layer; a second insulating layer deposited on the second metal wiring layer, defining a hole; a conductive bonding layer disposed on the second metal wiring layer so as to fill the hole; and a semiconductor light emitting device electrically connected to the second metal wiring layer by the conductive bonding layer, wherein the first metal layer blocks diffusion of the second metal layer.

According to an embodiment, the second metal wiring layer may include two pairs of the metal layers, and the second metal layer may be disposed on the first metal layer.

According to an embodiment, the conductive bonding layer may contain Sn.

According to an embodiment, the first metal layer may contain Cu.

According to an embodiment, the first metal layer may have a thickness in a range from 200 to 700 nm.

According to an embodiment, the second metal layer may contain at least one of Mo or Ti.

According to an embodiment, the second metal layer may have a thickness in a range from 10 to 100 nm.

According to another aspect, a substrate; a plurality of first metal wiring layers disposed on the substrate; a first insulating layer deposited on the substrate to cover the first metal wiring layer; a second metal wiring layer disposed on the first insulating layer and including at least portions spaced apart from each other; and a second insulating layer deposited on the second metal wiring layer, wherein the second metal wiring layer includes: at least one first metal layer having a first conductivity; and at least one second metal layer having a higher conductivity than the first metal layer, wherein the first metal layer blocks diffusion of the second metal layer.

According to an embodiment, the first metal layer and the second metal layer may be alternately stacked.

According to an embodiment, the first metal layer and the second metal layer may form a pair, wherein the second metal layer may be deposited on the first metal layer, and wherein the second metal wiring layer may be a structure including two pairs of the first metal layer and the second metal layer.

According to an embodiment, the second insulating layer may have a hole disposed on a portion of an upper surface of the second metal wiring layer.

According to an embodiment, the device may further include a conductive bonding layer disposed on the upper surface of the second metal wiring layer and at least a portion of an upper surface of the second insulating layer so as to fill the hole.

According to an embodiment, the device may further include a semiconductor light emitting device disposed on a portion of the conductive bonding layer and electrically connected to the second metal wiring layer via the conductive bonding layer; and a switching device disposed on a portion of the conductive bonding layer and controlling the semiconductor light emitting device.

According to an embodiment, the switching device may include a metal-oxide semiconductor field-effect-transistor (MOSFET).

According to an embodiment, the switching device may include a thin film transistor (TFT).

According to still another aspect, a method for manufacturing a display device including a semiconductor light emitting device includes depositing a first insulating layer on a substrate patterned with a plurality of first metal wiring layers; forming, on the first insulating layer, a second metal wiring layer including at least one first metal layer having a first conductivity and at least one second metal layer having a higher conductivity than the first metal layer; forming a second insulating layer deposited on a portion of the second metal wiring layer while defining a hole therein so as to be connected to the semiconductor light emitting device; disposing a conductive bonding layer on the second metal wiring layer so as to fill the hole; and disposing the semiconductor light emitting device on the second insulating layer so as to be connected to the second metal wiring layer via the conductive bonding layer.

According to an embodiment, the method may further include disposing a switching device on the second insulating layer so as to be connected to the second metal wiring layer via the conductive bonding layer.

According to an embodiment, the forming of the second metal wiring layer includes: patterning the first metal layer and the second metal layer using a same etchant.

### Advantageous Effects

According to the embodiments, the metal wiring may be prevented from being disconnected using the conductive bonding layer for connecting the substrate and the semiconductor light emitting device to each other.

According to embodiments, the bonding strength of the semiconductor light emitting device bonded onto the substrate may be increased.

According to the embodiments, as the MOSFETs are used, there is no need to manufacture the thin film transistor (TFT), so that the manufacturing efficiency may be improved and the display panel manufacturing cost may be reduced.

According to the embodiments, as the thin film transistor is used, the cost of the chip to which the MOSFET is applied may be reduced, thereby reducing the backlight manufacturing cost.

According to embodiments, the plurality of metal layers may be patterned at once using the same etchant. Therefore, the stable chip bonding is possible via the simple process not only in the case of the four-layer film including the two first metal layers and the two second metal layers, but also in the case of the six-layer film including the three first metal layers and the three second metal layers.

Furthermore, according to another embodiment of the present disclosure, additional advantageous and advantageous effects not mentioned herein may be understood by those skilled in the art upon examination of the entirety of the specification and drawings.

### BRIEF DESCRIPTION OF THE DRAWINGS

FIG. 1 is a cross-sectional view showing a backlight unit according to embodiments.

FIG. 2 is a cross-sectional view showing a backlight unit in which a semiconductor light emitting device is installed with respect to FIG. 1.

FIG. 3 is a cross-sectional view showing a backlight unit according to embodiments.

FIG. 4 is a cross-sectional view of a backlight unit in which a semiconductor light emitting device is installed with respect to FIG. 3.

FIG. 5 is a schematic cross-sectional view of a backlight unit of a display device according to embodiments.

FIG. 6 is a schematic cross-sectional view of a display device in which a semiconductor light emitting device is deposited with respect to FIG. 5.

FIG. 7 is a circuit diagram schematically illustrating a structure of a display device according to embodiments.

FIG. 8 is a cross-sectional view schematically illustrating a display device in which a semiconductor light emitting device is deposited with respect to FIG. 5.

FIG. 9 is a flowchart illustrating a method for manufacturing a display device according to embodiments.

### DETAILED DESCRIPTION

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining at least two or more drawings are also within the scope of the present disclosure.

In addition, when an element such as a layer, region or module is described as being “on” another element, it is to be understood that the element may be directly on the other element or there may be an intermediate element between them.

The display device described herein is a concept including all display devices that display information with a unit pixel or a set of unit pixels. Therefore, the display device may be applied not only to finished products but also to parts. For example, a panel corresponding to a part of a digital TV also independently corresponds to the display device in the present specification. The finished products include a mobile phone, a smartphone, a laptop, a digital broadcasting terminal, a personal digital assistant (PDA), a portable multimedia player (PMP), a navigation system, a slate PC, a tablet, an Ultrabook, a digital TV, a desktop computer, and the like.

However, it will be readily apparent to those skilled in the art that the configuration according to the embodiments described herein is applicable even to a new product that will be developed later as a display device.

In addition, the semiconductor light emitting device mentioned in this specification is a concept including an LED, a micro LED, and the like.

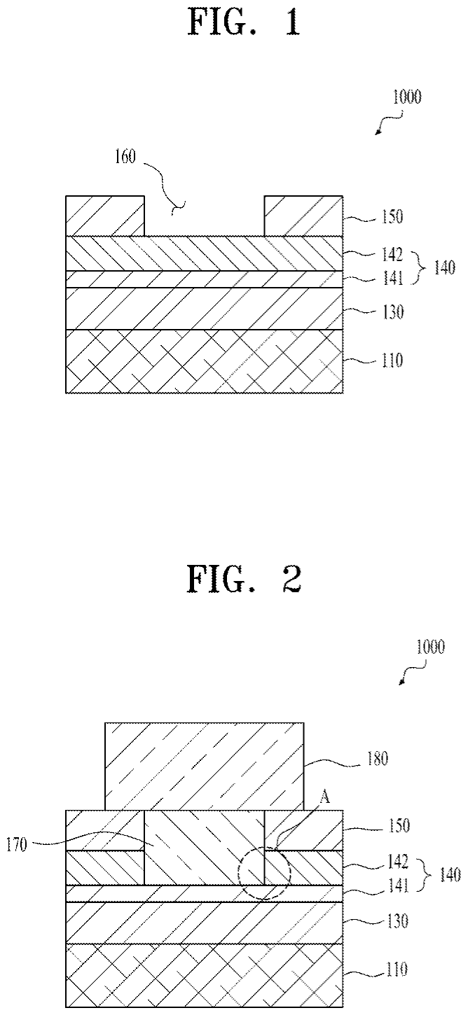

FIG. 1 is a cross-sectional view showing a backlight unit according to embodiments.

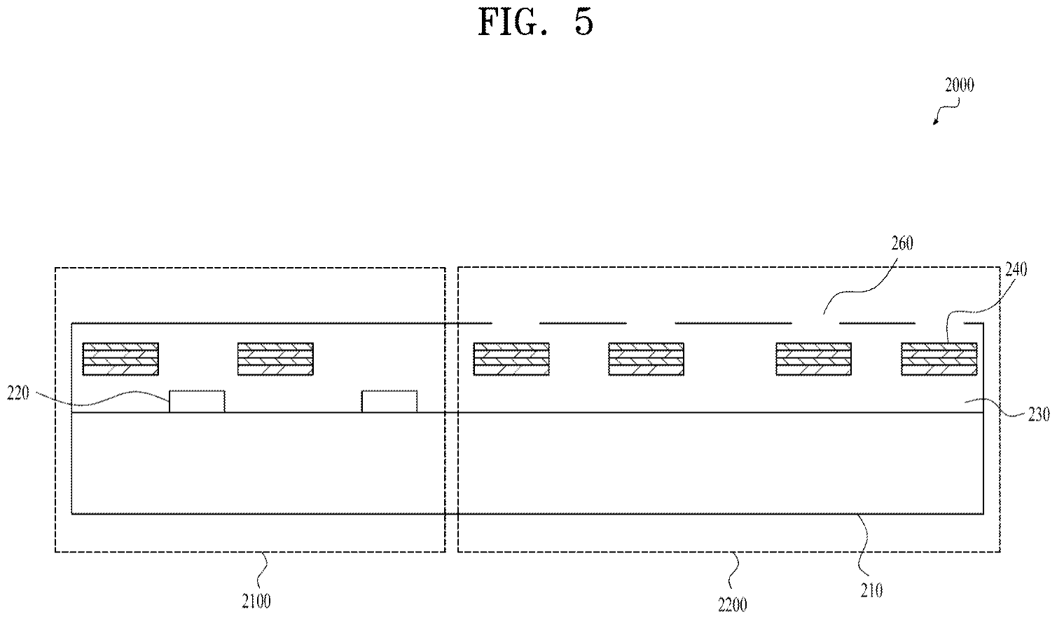

A backlight unit 1000 may include a substrate 110 on which a first metal wiring layer 220 (see FIG. 5) is formed, a first insulating layer 130 disposed on the substrate 110, a second metal wiring layer 140 disposed on the first insulating layer 130, and a second insulating layer 150 formed on the second metal wiring layer 140.

The substrate 110 may include the first metal wiring layer for applying an electrical signal to a semiconductor light emitting device 180 to be described later. The substrate 110 may be, for example, a glass substrate, but may not be limited thereto.

The first insulating layer 130 may be disposed on the substrate 110. The first insulating layer 130 may contain silicon or oxygen, which is an insulating inorganic material, and may contain, for example, SiO2 or SiNx, but may not be limited thereto.

The second metal wiring layer 140 may be formed on the first insulating layer 130. The second metal wiring layer 140 may include a first metal layer 141 and a second metal layer 142, and the second metal layer 142 may be positioned on the first metal layer 141.

By depositing the first metal layer 141 between the first insulating layer 130 and the second metal layer 142, adhesion between the first insulating layer 130 and the second metal layer 142 may be improved. In this regard, a thickness of the first metal layer 141 may be in a range from 10 to 100 nm, but may not be limited thereto. In this regard, a thickness of the second metal layer 142 may be in a range from 200 to 700 nm, but may not be limited thereto.

The second metal layer 142 may contain a material having higher electrical conductivity than the first metal layer 141. For example, the first metal layer 141 may contain Mo, Ti, or Mo/Ti, and the second metal layer 142 may contain Cu. However, the present disclosure is not limited thereto.

The second metal wiring layer 140 may be deposited on at least a portion of the first insulating layer 130. The second insulating layer 150 may be formed on the second metal wiring layer 140 to surround the second metal wiring layer 140. The second insulating layer 150 may use the same material as the first insulating layer and may contain silicon or oxygen as the insulating inorganic material. For example, the second insulating layer 150 may include SiO2, SiNx, or the like, but may not be limited thereto.

The second insulating layer 150 may include a hole 160 defined therein for depositing the semiconductor light emitting device 180 to be described later. That is, the hole 160 may be defined in the second insulating layer 150 so as to expose a portion of the second metal wiring layer 140 to attach the semiconductor light emitting device 180 to the backlight unit 1000.

FIG. 2 is a cross-sectional view showing a backlight unit in which a semiconductor light emitting device is installed with respect to FIG. 1.

In the device formed in FIG. 1, the backlight unit 1000 may further include a conductive bonding layer 170 filled in the hole 160 defined in the second insulating layer 150, and the semiconductor light emitting device 180 disposed on the second insulating layer.

The conductive bonding layer 170 may be formed in the hole 160 so as to bond the semiconductor light emitting device 180 onto the second insulating layer 150. That is, the semiconductor light emitting device 180 may be bonded onto the second insulating layer 150 while being electrically connected to the second metal wiring layer 140 via the conductive bonding layer 170.

The conductive bonding layer 170 may contain a metal having a lower melting point than the semiconductor light emitting device 180 and the second metal wiring layer 140. For example, the conductive bonding layer 170 may be solder cream containing Sn, and may be, for example, a Sn—Ag—Cu alloy. Specifically, the conductive bonding layer 170 may be an alloy of Sn-Ag3%-Cu0.5%, but may not be limited thereto.

However, in the process of bonding the semiconductor light emitting device 180 onto the second insulating layer 150, the exposed second metal layer 142 and the conductive bonding layer 170 may form an alloy, and the melted second metal layer 142 may cause disconnection of the second metal wiring layer 140. That is, as shown in A in FIG. 2, a weak portion may be generated from the disconnection. For example, during the SMT process, the second metal layer 142 containing Cu and the conductive bonding layer 170 containing Sn melt together to form a Sn—Cu alloy, resulting in the disconnection and a loss of the substrate.

Therefore, hereinafter, a method for preventing the disconnection of the metal wiring layer of the embodiments is presented.

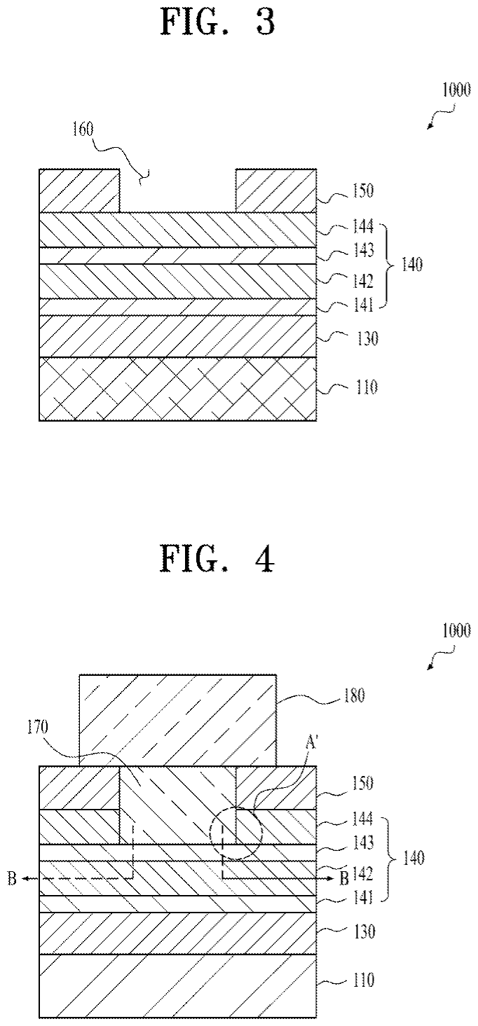

FIG. 3 is a cross-sectional view showing a backlight unit according to embodiments.

The backlight unit 1000 may include the substrate 110 on which the first metal wiring layer 220 (see FIG. 5) is formed, the first insulating layer 130 disposed on the substrate 110, the second metal wiring layer 140 deposited on the first insulating layer 130, and the second insulating layer 150 formed on the second metal wiring layer 140.

The substrate 110 may include the first metal wiring layer for applying the electrical signal to the semiconductor light emitting device 180 to be described later. The substrate 110 may be, for example, the glass substrate, but may not be limited thereto.

The first insulating layer 130 may be disposed on the substrate 110. The first insulating layer 130 may contain silicon or oxygen, which is the insulating inorganic material, and may contain, for example, SiO2, SiNx, or the like, but may not be limited thereto.

The second metal wiring layer 140 may be formed on the first insulating layer 130. The second metal wiring layer 140 may include a plurality of pairs of metal layers including the first metal layer 141 and the second metal layer 142, and the second metal layer 142 may be positioned on the first metal layer 141 in the metal layer.

According to embodiments, the second metal wiring layer 140 may be composed of two pairs of metal layers. That is, the second metal wiring layer 140 may include two first metal layers 141 and two second metal layers 142, and the first metal layer 141 and the second metal layer 142 may be alternately disposed. Hereinafter, a metal layer located below and a metal layer located above among the first metal layers are respectively referred to as the first metal layer 141 and a third metal layer 143, and a metal layer located below and a metal layer located above among the second metal layers are respectively referred to as the second metal layer 142 and a fourth metal layer 144. That is, the respective metal layers are referred to as the first, second, third, and fourth metal layers 141, 142, 143, and 144 in an order from the substrate toward an upper surface.

The second metal wiring layer 140 may include the first metal layer 141 disposed on the first insulating layer 130, the second metal layer 142 deposited on the first metal layer, the third metal layer 143 deposited on the second metal layer, and the fourth metal layer 144 deposited on the third metal layer.

The first metal layer 141 may be deposited on the first insulating layer 130 to improve a strength of bonding between the second metal layer 142 and the first insulating layer 130. For example, the first metal layer 141 may contain Mo, Ti, or Mo/Ti, but may not be limited thereto. The first metal layer 141 may have the thickness in the range from 10 to 100 nm, but may not be limited thereto.

The second metal layer 142 may be deposited on the first metal layer 141 and may contain the metal having the higher electrical conductivity than the first metal layer 141. In addition, the second metal layer 142 may contain a low-resistance metal capable of covering a high current injected into the semiconductor light emitting device 180. For example, the second metal layer 142 may contain Cu, but may not be limited thereto. The second metal layer 142 may have the thickness in the range from 200 to 700 nm, but may not be limited thereto.

The third metal layer 143 may be deposited on the second metal layer 142, and may use a metal with a high melting point to block diffusion of metal ions from the second metal layer 144 during the SMT process. For example, the third metal layer 143 may use the same metal as the first metal layer 141 and may contain Mo, Ti, or Mo/Ti, but may not be limited thereto. The third metal layer 143 may have a thickness in a range from 200 to 700 nm, but may not be limited thereto.

The fourth metal layer 144 may be deposited on the third metal layer 143 and bonded to the semiconductor light emitting device 180 via the conductive bonding layer 170 to be described later. The fourth metal layer 144 may contain the same metal as the second metal layer 142, and may contain, for example, Cu, but may not be limited thereto. The fourth metal layer 144 may have a thickness in a range from 200 to 700 nm, but may not be limited thereto.

Although FIG. 3 shows the backlight unit in which the first to fourth metal layers 141 to 144 are stacked, a plurality of pairs of metal layers having different conductivity may be further stacked. Specifically, a fifth metal layer may be deposited on the fourth metal layer, and a sixth metal layer may be deposited on the fifth metal layer. In this regard, the fifth metal layer may contain the same metal as the first metal layer and the third metal layer, and the sixth metal layer may contain the same metal as the second metal layer and the fourth metal layer.

FIG. 4 is a cross-sectional view of a backlight unit in which a semiconductor light emitting device is installed with respect to FIG. 3.

In the device formed in FIG. 3, the backlight unit 1000 may further include the conductive bonding layer 170 filled in the hole 160 defined in the second insulating layer 150, and the semiconductor light emitting device 180 disposed on the second insulating layer 150.

The conductive bonding layer 170 may be formed in the hole 160 to bond the semiconductor light emitting device 180 onto the second insulating layer 150. That is, the semiconductor light emitting device 180 may be bonded onto the second insulating layer 150 while being electrically connected to the second metal wiring layer 140 via the conductive bonding layer 170.

The conductive bonding layer 170 may contain the metal having the lower melting point than the semiconductor light emitting device 180 and the second metal wiring layer 140. For example, the conductive bonding layer 170 may serve as a solder. For example, the conductive bonding layer 170 may be the solder cream containing Sn, and may be, for example, the Sn—Ag—Cu alloy. Specifically, the conductive bonding layer 170 may be the alloy of Sn-Ag3%-Cu0.5%, but may not be limited thereto.

In the process of bonding the semiconductor light emitting device 180 onto the second insulating layer 150, the exposed fourth metal layer 144 and the conductive bonding layer 170 may form an alloy. That is, as shown in A′ in FIG. 4, for example, during the SMT process, the fourth metal layer 144 containing Cu and the conductive bonding layer 170 containing Sn melt together to form a Sn—Cu alloy.

In this regard, the third metal layer 143 may prevent the metal contained in the second metal layer 142 from being diffused and melted into the conductive bonding layer 170 to form an alloy. Specifically, the metal ions contained in the second metal layer 142 may not diffuse toward the conductive bonding layer 170, but remain and facilitate current flow between the semiconductor light emitting device 180 and the substrate including the metal wiring layer. For example, when Cu is contained in the second metal layer 142, Cu, which does not diffuse toward the conductive bonding layer 170 by the third metal layer 143, may allow the current to flow through a path indicated by an arrow B in FIG. 4 without the disconnection.

FIG. 5 is a schematic cross-sectional view of a backlight unit of a display device according to embodiments. For duplicated components, refer to the above description.

A display device 2000 may include a substrate 210, the plurality of first metal wiring layers 220 formed on the substrate 210, an insulating layer 230 deposited on the substrate 210 while covering the first metal wiring layers 220, and a second metal wiring layer 240 deposited within the insulating layer.

The second metal wiring layer 240 may include a plurality of pairs of metal layers including a first metal layer and a second metal layer. The first metal layer may be deposited on the second metal layer. The first metal layer may contain a first metal having a first conductivity, and the second metal layer may contain a second metal having a second conductivity. In this regard, the second metal may have higher electrical conductivity than the first metal. For example, the first metal may be Cu, and the second metal may be one of Mo, Ti, and Mo/Ti, but may not be limited thereto. In FIG. 5, a structure in which two pairs of metal layers are stacked is illustrated, but the present disclosure is not limited thereto, and two or more pairs of metal layers may be stacked.

The first metal wiring layer 220 and the second metal wiring layer 240 may contain the same metal or different metals. The first metal wiring layer 220 and the second metal wiring layer 240 may have a thin film shape, but may not be limited thereto.

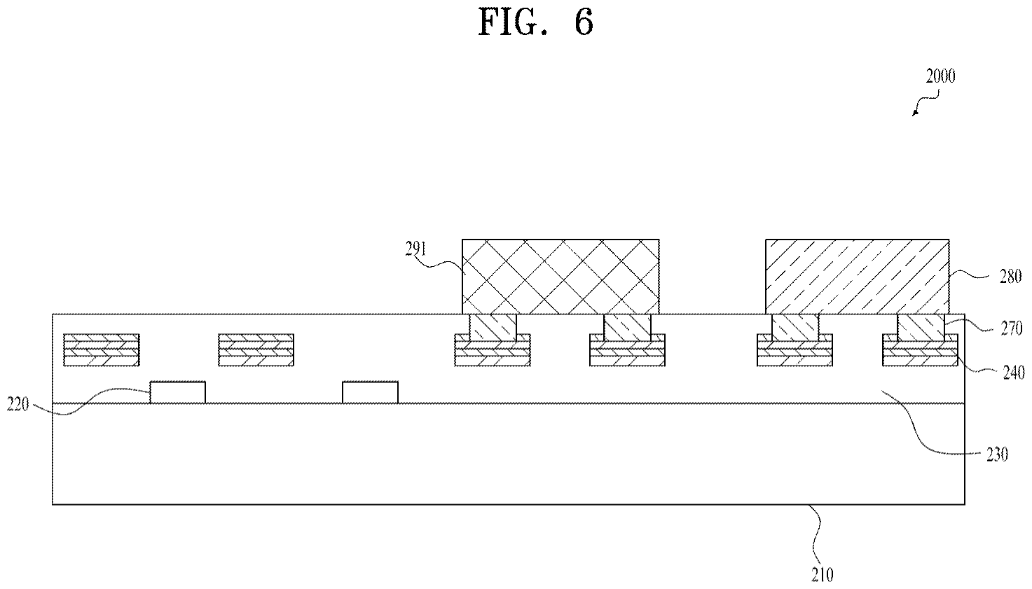

The display device 2000 may include an electrical signal transmitting wiring area 2100 and a chip attachment pad area 2200. The electrical signal transmitting wiring area 2100 may include two or more first metal wiring layers 220 and two or more second metal wiring layers 240. The chip attachment pad area 2200 may include a light emitting device 280 (see FIG. 6) and a switching device 290 (see FIG. 6). To this end, the chip attachment pad area 2200 may include a hole 260 in the insulating layer 230. The hole 260 may be defined in the insulating layer 230 so as to expose a portion of the second metal wiring layer 240.

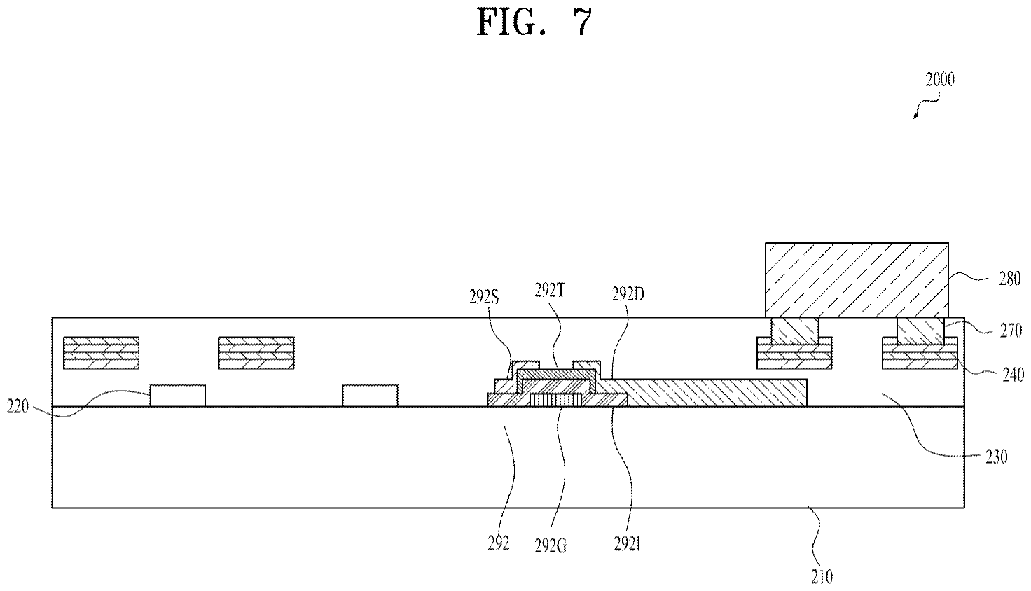

A configuration further including the semiconductor light emitting device 280 and the switching device 290 in the display device 2000 with respect to FIG. 5 will be described in detail below. The switching device 290 may include an device that controls the semiconductor light emitting device 280. The switching device 290 may include, for example, a thin film transistor (TFT) or a metal oxide semiconductor field effect transistor (MOSFET), but may not be limited thereto. FIG. 6 shows an embodiment including the MOSFET, and FIG. 7 shows an embodiment including the TFT. A description thereof will be made below.

FIG. 6 is a schematic cross-sectional view of a display device in which a semiconductor light emitting device is deposited with respect to FIG. 5.

The display device 2000 may further include the semiconductor light emitting device 280, the switching device 290, and a conductive bonding layer 270 for connecting the second metal wiring layer 240 to the semiconductor light emitting device 280 and a MOSFET 291, with respect to the display device in FIG. 5 described above.

The conductive bonding layer 270 may be formed in the hole 160 to bond the semiconductor light emitting device 280 and the MOSFET 291 onto a second insulating layer 250. That is, the semiconductor light emitting device 280 and the MOSFET 291 may be bonded onto the second insulating layer 250 while being electrically connected to the second metal wiring layer 240 by the conductive bonding layer 270.

FIG. 7 is a circuit diagram schematically illustrating a structure of a display device according to embodiments.

The display device 2000 may include a unit compartment area including switching device 291s for controlling the semiconductor light emitting device 280 and driving means 291d for driving the semiconductor light emitting device 280.

The unit compartment area may include the two MOSFETs 291. As shown in FIG. 7, the MOSFETs 291 may include the two MOSFETs 291 including the switching MOSFET 291s and the driving MOSFET 291d. The switching MOSFET 291s may be connected to a scan line Gate to perform a switching operation, and the driving MOSFET 291d may be connected to the semiconductor light emitting device 280.

The MOSFETs 291 are connected to each unit compartment area, so that the semiconductor light emitting device 280 in each unit compartment area may be driven. A unit light-emitting area may be defined by the MOSFETs 291 connected to a data line Data and the scan line Gate.

In addition, each unit compartment area may include a gate-off voltage line Vss connected to the driving MOSFET 291d and a gate-on voltage line VDD connected to an anode of the light emitting device 280. In this regard, the gate-on voltage VDD corresponds to the highest voltage applied to drive the light emitting device 280.

Unlike that shown in FIG. 7, the switching device 291s may include two or more MOSFETs for each pixel area. For example, the switching device 291s may include two switching MOSFETs. In this regard, each switching MOSFET may be connected in parallel with the scan line Gate and may be connected in series with the data line Data. In this regard, the two switching MOSFETs may be connected to each other such that source terminals thereof face each other.

The unit compartment area according to embodiments may correspond to a unit sub-pixel area. That is, when the unit compartment area of the embodiments is applied to a display device, the unit compartment area may correspond to a unit sub-pixel. In addition, when the unit compartment area of the embodiments is applied to a backlight unit, the unit compartment area may be a unit control area of local dimming driving. As such, multiple unit compartment areas may be arranged on the display device or the backlight unit. In addition, the unit compartment area may be defined in other devices for individual driving other than the display device or the backlight unit.

When the MOSFET 291 is used as the switching device 290, a cost of the substrate may be saved in a process of manufacturing a photo mask, so that there is an economical effect. That is, because the display device according to the embodiments does not require manufacturing of a thin film transistor (TFT), manufacturing efficiency may be improved and a display panel manufacturing cost may be reduced.

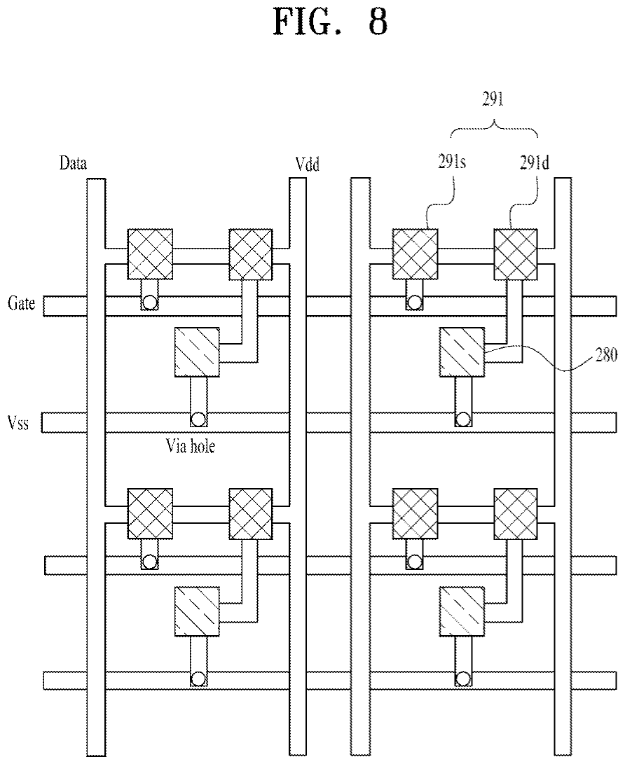

FIG. 8 is a cross-sectional view schematically illustrating a display device in which a semiconductor light emitting device is deposited with respect to FIG. 5.

The display device 2000 may further include the semiconductor light emitting device 280, the switching device 290, and the conductive bonding layer 270 for connecting the second metal wiring layer 240 to the semiconductor light emitting device 280 and a TFT 292, with respect to the display device in FIG. 5 described above.

The conductive bonding layer 270 may be formed in the hole 260 to bond the semiconductor light emitting device 280 and the TFT 292 onto the second insulating layer 250. That is, the semiconductor light emitting device 280 and the TFT 292 may be bonded onto the second insulating layer 250 while being electrically connected to the second metal wiring layer 240 by the conductive bonding layer 270.

The display device 2000 may include the TFT 292. In the TFT 292, a gate electrode 292G and an insulating layer 2921 may be positioned on the substrate 210, a semiconductor layer 292T may be positioned on such insulating layer, and a source electrode 292S and a drain electrode 292D may be positioned on both sides of such semiconductor layer 292T. Such source electrode 292S and drain electrode 292D may be covered with the insulating layer 230.

When the TFT 292 is used as the switching device 290, as the thin film transistor (TFT) is used, a cost of the chip to which the MOSFET is applied may be reduced, thereby reducing a backlight manufacturing cost.

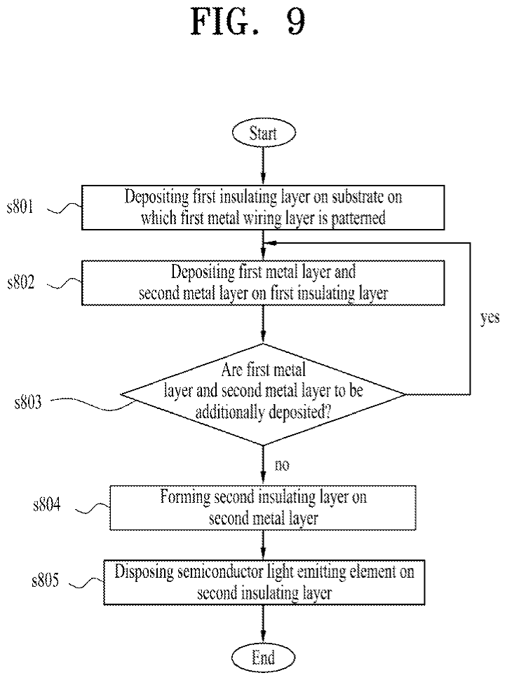

FIG. 9 is a flowchart illustrating a method for manufacturing a display device according to embodiments.

The method for manufacturing the display device according to the embodiments includes depositing the first insulating layer on the substrate on which one or more first metal wiring layers are patterned (s901). The substrate 110 may be, for example, the glass substrate, but may not be limited thereto. The first insulating layer 130 may be deposited on the substrate 110. The first insulating layer 130 may contain silicon or oxygen, which is the insulating inorganic material, and may contain, for example, SiO2, or SiNx, or the like, but may not be limited thereto.

The method for manufacturing the display device according to the embodiments includes depositing the second metal wiring layer in which the plurality of pairs of metal layers including the first metal layer and the second metal layer are stacked on the substrate including the first insulating layer (s902). The first metal layer has the first conductivity and the second metal layer has the second conductivity, and the second conductivity is greater than the first conductivity. In this regard, the thickness of the first metal layer 141 may be in the range from 10 to 100 nm, but may not be limited thereto. In this regard, the thickness of the second metal layer 142 may be in the range from 200 to 700 nm, but may not be limited thereto. The second metal layer 142 may contain the material having the higher electrical conductivity than the first metal layer 141. For example, the first metal layer 141 may contain Mo, Ti, or Mo/Ti, and the second metal layer 142 may contain Cu. However, the present disclosure may not be limited thereto. In this regard, the plurality of pairs of metal layers may be stacked (s903).

The forming of the second metal wiring layer may include patterning the plurality of metal layers at once using the same etchant. Therefore, stable chip bonding is possible via a simple process not only in a case of a four-layer film including the two first metal layers and the two second metal layers, but also in a case of a six-layer film including three first metal layers and three second metal layers.

The method for manufacturing the display device according to the embodiments includes forming the second insulating layer for defining therein the hole to expose the second metal wiring layer on the second metal layer (s903). The conductive bonding layer may be filled in the defined hole to connect the semiconductor light emitting device to be described later with the substrate.

The method for manufacturing the display device according to the embodiments includes disposing at least one of the semiconductor light emitting device and the switching device on the second insulating layer (S905). In this regard, the switching device may be the TFT or the MOSFET, but may be anything capable of driving and controlling the semiconductor light emitting device.

As such, according to the embodiments, the metal wiring may be prevented from being disconnected using the conductive bonding layer for connecting the substrate and the semiconductor light emitting device to each other.

According to embodiments, the bonding strength of the semiconductor light emitting device bonded onto the substrate may be increased.

According to the embodiments, as the MOSFETs are used, there is no need to manufacture the thin film transistor (TFT), so that the manufacturing efficiency may be improved and the display panel manufacturing cost may be reduced.

According to the embodiments, as the thin film transistor is used, the cost of the chip to which the MOSFET is applied may be reduced, thereby reducing the backlight manufacturing cost.

According to embodiments, the plurality of metal layers may be patterned at once using the same etchant. Therefore, the stable chip bonding is possible via the simple process not only in the case of the four-layer film including the two first metal layers and the two second metal layers, but also in the case of the six-layer film including the three first metal layers and the three second metal layers.

The above description is merely illustrative of the technical idea of the present disclosure. Those of ordinary skill in the art to which the present disclosure pertains will be able to make various modifications and variations without departing from the essential characteristics of the present disclosure.

Therefore, embodiments disclosed in the present disclosure are not intended to limit the technical idea of the present disclosure, but to describe, and the scope of the technical idea of the present disclosure is not limited by such embodiments.

The scope of protection of the present disclosure should be interpreted by the claims below, and all technical ideas within the scope equivalent thereto should be construed as being included in the scope of the present disclosure.

1. A backlight unit comprising:
a substrate including a first metal wiring layer;
a first insulating layer disposed on the substrate so as to cover the first metal wiring layer;
a second metal wiring layer disposed on the first insulating layer, wherein a plurality of pairs of metal layers including a first metal layer having a first conductivity and a second metal layer having a higher conductivity than the first metal layer are stacked in the second metal wiring layer;
a second insulating layer deposited on the second metal wiring layer, defining a hole;
a conductive bonding layer disposed on the second metal wiring layer so as to fill the hole; and
a semiconductor light emitting device electrically connected to the second metal wiring layer by the conductive bonding layer,
wherein the first metal layer blocks diffusion of the second metal layer.

2. The backlight unit of claim 1, wherein the second metal wiring layer includes two pairs of the metal layers,
wherein the second metal layer is disposed on the first metal layer.

3. The backlight unit of claim 1, wherein the conductive bonding layer contains Sn.

4. The backlight unit of claim 1, wherein the first metal layer contains Cu.

5. The backlight unit of claim 4, wherein the first metal layer has a thickness in a range from 200 to 700 nm.

6. The backlight unit of claim 1, wherein the second metal layer contains at least one of Mo or Ti.

7. The backlight unit of claim 6, wherein the second metal layer has a thickness in a range from 10 to 100 nm.

8. A display device comprising:
a substrate;
a plurality of first metal wiring layers disposed on the substrate;
a first insulating layer deposited on the substrate to cover the first metal wiring layer;
a second metal wiring layer disposed on the first insulating layer and including at least portions spaced apart from each other; and
a second insulating layer deposited on the second metal wiring layer,
wherein the second metal wiring layer includes:
at least one first metal layer having a first conductivity; and
at least one second metal layer having a higher conductivity than the first metal layer,
wherein the first metal layer blocks diffusion of the second metal layer.

9. The display device of claim 8, wherein the first metal layer and the second metal layer are alternately stacked.

10. The display device of claim 9, wherein the first metal layer and the second metal layer form a pair,
wherein the second metal layer is deposited on the first metal layer,
wherein the second metal wiring layer is a structure including two pairs of the first metal layer and the second metal layer.

11. The display device of claim 8, wherein the second insulating layer has a hole disposed on a portion of an upper surface of the second metal wiring layer.

12. The display device of claim 11, further comprising:
a conductive bonding layer disposed on the upper surface of the second metal wiring layer and at least a portion of an upper surface of the second insulating layer so as to fill the hole.

13. The display device of claim 12, further comprising:
a semiconductor light emitting device disposed on a portion of the conductive bonding layer and electrically connected to the second metal wiring layer via the conductive bonding layer; and
a switching device disposed on a portion of the conductive bonding layer and controlling the semiconductor light emitting device.

14. The display device of claim 13, wherein the switching device includes a metal-oxide semiconductor field-effect-transistor (MOSFET).

15. The display device of claim 13, wherein the switching device includes a thin film transistor (TFT).

16. A method for manufacturing a display device including a semiconductor light emitting device, the method comprising:
depositing a first insulating layer on a substrate patterned with a plurality of first metal wiring layers;
forming, on the first insulating layer, a second metal wiring layer including at least one first metal layer having a first conductivity and at least one second metal layer having a higher conductivity than the first metal layer;
forming a second insulating layer deposited on a portion of the second metal wiring layer while defining a hole therein so as to be connected to the semiconductor light emitting device;
disposing a conductive bonding layer on the second metal wiring layer so as to fill the hole; and
disposing the semiconductor light emitting device on the second insulating layer so as to be connected to the second metal wiring layer via the conductive bonding layer.

17. The method of claim 16, further comprising:
disposing a switching device on the second insulating layer so as to be connected to the second metal wiring layer via the conductive bonding layer.

18. The method of claim 16, wherein the forming of the second metal wiring layer includes:
patterning the first metal layer and the second metal layer using a same etchant.

19. The method of claim 16, wherein the second insulating layer has a hole disposed on a portion of an upper surface of the second metal wiring layer.

20. The method of claim 19, further comprising forming a conductive bonding layer on the upper surface of the second metal wiring layer and at least a portion of an upper surface of the second insulating layer so as to fill the hole.
